(19) United States
(12) Patent Application Publication
(10) Pub. No.: US 2026/0214792 A1
(43) Pub. Date: Jul. 23, 2026

(54) CIRCUIT BOARD STRUCTURE AND MANUFACTURING METHOD THEREOF

(71) Applicant: UNIMICRON TECHNOLOGY CORP., Taoyuan City (TW)

(72) Inventors: Wei-Yu LIAO, Taoyuan City (TW); Kai-Wei WANG, Taoyuan City (TW); Yan-Ting LAI, Taoyuan City (TW); Chun-Jui HUANG, Taoyuan City (TW); Ching-Sheng CHEN, Taoyuan City (TW)

(73) Assignee: UNIMICRON TECHNOLOGY CORP., Taoyuan City (TW)

(21) Appl. No.: 19/446,092

(22) Filed: Jan. 12, 2026

Related U.S. Application Data
(60) Provisional application No. 63/746,475, filed on Jan. 17, 2025.

(51) Int. Cl. H05K 1/02; H05K 3/46

(52) U.S. Cl. CPC H05K 1/0298; H05K 3/4644

(57) ABSTRACT

A circuit board structure and a manufacturing method thereof are provided. The circuit board structure includes a substrate, a circuit pattern, a buffer structure, and a dielectric layer. The circuit pattern is disposed on the substrate. The buffer structure is disposed on the substrate and is electrically insulated from the circuit pattern. The dielectric layer includes a first portion and a second portion. The first portion covers and is in contact with the upper surface of the circuit pattern. The second portion covers and is in contact with the upper surface of the buffer structure.

### CROSS REFERENCE TO RELATED APPLICATIONS

This application claims the benefit of U.S. provisional application No. 63/746,475, filed Jan. 17, 2025, the entirety of which is incorporated by reference herein.

### BACKGROUND OF THE INVENTION

### Field of the Invention

The present disclosure relates to circuit board structures, and, in particular, it relates to a circuit board structure with excellent uniformity of dielectric thickness, and a manufacturing method thereof.

### Description of the Related Art

As electronic devices are used more widely, user expectations as to their high performance requirements are also increasing. To meet these demands, the design of circuit board structures in electronic devices increasingly employs more complex circuit patterns than previous generations. However, these complex circuit patterns can result in uneven dielectric layer thickness, leading to the structural stability of the circuit board structure being insufficient. In other words, while existing circuit board structures and manufacturing methods thereof have generally met their intended purposes, they do not meet requirements in all respects. Therefore, there is still a need for improvements to circuit board structures and the manufacturing methods thereof.

### BRIEF SUMMARY OF THE INVENTION

According to some embodiments, a circuit board structure is provided. The circuit board structure includes a substrate, a circuit pattern, a buffer structure, and a dielectric layer. The circuit pattern is disposed on the substrate. The buffer structure is disposed on the substrate and is electrically insulated from the circuit pattern. The dielectric layer includes a first portion and a second portion. The first portion covers and is in contact with the upper surface of the circuit pattern. The second portion covers and is in contact with the upper surface of the buffer structure.

In some embodiments, the first portion and the circuit pattern together have a first thickness t1, and the second portion and the buffer structure together have a second thickness t2, wherein |(t1−t2)|≤30 μm.

In some embodiments, the first portion and the circuit pattern together have a first thickness t1, and the second portion and the buffer structure together have a second thickness t2, wherein |(t1−t2)|/(t1+t2)≤20%.

In some embodiments, the dielectric layer further includes a third portion covering and in contact with the upper surface of the substrate.

In some embodiments, the first portion and the circuit pattern together have a first thickness t1, and the third portion has a third thickness t3, and |(t1−t3)|≤30 μm.

In some embodiments, the first portion and the circuit pattern together have a first thickness t1, and the third portion has a third thickness t3, and |(t1−t3)|/(t1+t3)≤20%.

In some embodiments, the upper surface of the buffer structure is coplanar with the upper surface of the circuit pattern.

In some embodiments, a side surface of the buffer structure is not in contact with a side surface of the circuit pattern.

In some embodiments, the upper surface of the buffer structure is lower than the upper surface of the circuit pattern.

In some embodiments, a side surface of the buffer structure is in contact with a side surface of the circuit pattern.

In some embodiments, the circuit pattern defines a gap and the buffer structure fills at least 40% of the volume of the gap.

In some embodiments, the material of the buffer structure is different from the material of the dielectric layer.

According to some embodiments, a manufacturing method of a circuit board structure is provided. The manufacturing method of the circuit board structure includes: forming a circuit pattern on a substrate; disposing a buffer material on the substrate; curing the buffer material to form a buffer structure, wherein the buffer structure is electrically insulated from the circuit pattern; and performing a lamination process at a lamination temperature to form a dielectric layer on the circuit pattern and the buffer structure. The glass transition temperature or the melting point of the buffer structure is higher than the lamination temperature.

In some embodiments, the dielectric layer includes a first portion and a second portion. The first portion covers and is in contact with the upper surface of the circuit pattern. The second portion covers and is in contact with the upper surface of the buffer structure.

In some embodiments, the first portion and the circuit pattern together have a first thickness t1, the second portion and the buffer structure together have a second thickness t2, and |(t1−t2)|≤30 μm.

In some embodiments, the first portion and the circuit pattern together have a first thickness t1, the second portion and the buffer structure together have a second thickness t2, and |(t1−t2)|/(t1+t2)≤20%.

In some embodiments, the first portion and the circuit pattern together have a first thickness t1, and the dielectric layer further includes a third portion. The third portion covers and is in contact with the upper surface of the substrate, wherein the third portion has a third thickness t3, and |(t1−t3)|≤30 μm.

In some embodiments, the first portion and the circuit pattern together have a first thickness t1, and the dielectric layer further includes a third portion. The third portion covers and is in contact with the upper surface of the substrate, wherein the third portion has a third thickness t3, and |(t1−t3)|/(t1+t3)≤20%.

In some embodiments, the circuit pattern defines a gap and the buffer structure fills at least 40% of the volume of the gap.

In some embodiments, the step of disposing the buffer material on the substrate includes disposing the buffer material on the substrate using a screen printing process.

The circuit board structure and the manufacturing method thereof of the present disclosure may be applied in a variety of electric devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 5 are cross-sectional schematic views illustrating a circuit board structure at different stages in the manufacturing method according to some embodiments of the present disclosure; and

FIGS. 6A to 6D are enlarged cross-sectional schematic views illustrating the buffer structure and the circuit pattern according to some embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly describing some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguish an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection may also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the present disclosure or conflict with each other.

Unless otherwise defined, all terms (including technical and scientific terms) used herein have the same meaning as commonly understood by a person of ordinary skill in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In circuit board structures, multiple circuit patterns can be disposed on a substrate to achieve specific functions. The overlap area between these circuit patterns and the substrate (e.g., viewed in a projected manner) can be defined as circuit density or residual copper ratio (detailed calculations are described below). Different circuit patterns may have differences in circuit density (or residual copper ratio). As the number and complexity of circuit patterns increase, the differences in circuit density (or residual copper ratio) become more significant. This makes it difficult for the dielectric material disposed on the circuit pattern to form a blanket structure. For example, in areas with high circuit density, the dielectric material is difficult to fill the gaps between lines by flow. On the other hand, in areas with low circuit density, the dielectric material may create a collapsed surface due to excessive filling of the gaps between lines. As a result, poor dielectric thickness uniformity may occur, which in turn affects subsequent processes or device stability.

To address at least some of the aforementioned problems, the present disclosure provides buffer structures disposed in gaps between adjacent lines of a circuit pattern or in copper-free areas between circuit patterns (i.e., areas where no circuit pattern is disposed), so as to alleviate issues caused by non-uniform circuit density. Specifically, the buffer structures can partially fill or completely fill these regions and serve as supports, thereby allowing a dielectric layer formed in subsequent processes to be disposed in a flat manner. In other words, the present disclosure provides a circuit board structure with excellent dielectric thickness uniformity and a manufacturing method thereof.

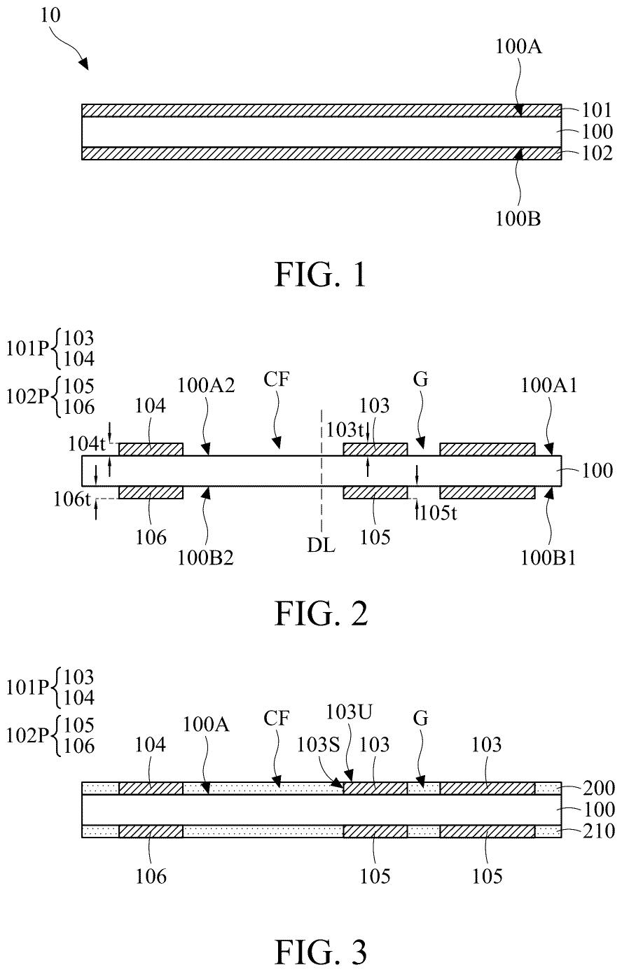

FIGS. 1 to 5 are schematic cross-sectional views illustrating the circuit board structure at different stages in the manufacturing process according to some embodiments of the present disclosure. It should be noted that, for simplicity and ease of understanding, the figures in the present disclosure may exaggerate the dimensions of components and the proportions between them. Furthermore, the figures in the present disclosure may omit some components in the circuit board structure, but a person having ordinary skills in the art will understand that the circuit board structure may also include other common components, such as active components, passive components, pads, and redistribution layers (RDLs).

As shown in FIG. 1, the base substrate 10 is provided. The base substrate 10 may include the substrate 100, the conductor layer 101, and the conductor layer 102, wherein the conductor layer 101 and the conductor layer 102 are respectively disposed on the upper surface 100A and the lower surface 100B of the substrate 100.

In some embodiments, the substrate 100 may include polymeric materials, fibrous materials, prepreg, other suitable materials, or a combination thereof, but the present disclosure is not limited thereto. For example, polymeric materials may include epoxy resin, polyimide (PI), polypropylene (PP), other suitable polymeric materials, or a combination thereof, but the present disclosure is not limited thereto. For example, fibrous materials may include carbon fiber, glass fiber, other suitable fibrous materials, or a combination thereof, but the present disclosure is not limited thereto. In some embodiments, the conductor layer 101 and/or the conductor layer 102 may include aluminum (Al), copper (Cu), an alloy thereof, or a compound thereof, but the present disclosure is not limited thereto. For example, copper alloys or compounds may include brass, phosphor bronze, beryllium bronze, or oxygen-free copper, but the present disclosure is not limited thereto. In some embodiments, the base substrate 10 is a copper foil substrate.

As shown in FIG. 2, following the steps described above, the conductor layer 101 is patterned to form the circuit pattern 101P on the upper surface 100A of the substrate 100. For example, the circuit pattern 101P may include the first circuit pattern 103 and the second circuit pattern 104. In some embodiments, multiple circuit patterns located on the same side of the base substrate 10 may be separated from each other to achieve different functions. For example, the first circuit pattern 103 and the second circuit pattern 104 on the upper surface 100A of the substrate 100 may be used as an audio signal transmission line and an image signal transmission line, respectively, but the present disclosure is not limited thereto. Alternatively, these circuit patterns may also be different regions of a single circuit and together perform a specific function. For example, the first circuit pattern 103 and the second circuit pattern 104 on the upper surface 100A of the substrate 100 may be used together as a power transmission line, but the present disclosure is not limited thereto.

In some embodiments, the circuit pattern 101P has a substantially uniform thickness. For example, the first circuit pattern 103 has the first circuit thickness 103t, the second circuit pattern 104 has the second circuit thickness 104t, and the first circuit thickness 103t is substantially the same as the second circuit thickness 104t. However, the present disclosure is not limited thereto. In other embodiments, the first circuit thickness 103t may be different from the second circuit thickness 104t.

Following the steps described above, the conductor layer 102 is patterned to form the circuit pattern 102P on the lower surface 100B of the substrate 100. For example, the circuit pattern 102P may include the third circuit pattern 105 and the fourth circuit pattern 106. Similarly, these circuit patterns may each perform different specific functions, or together perform a certain specific function.

In some embodiments, the circuit pattern 102P has a substantially uniform thickness. For example, the third circuit pattern 105 has the third circuit thickness 105t, the fourth circuit pattern 106 has the fourth circuit thickness 106t, and the third circuit thickness 105t is substantially the same as the fourth circuit thickness 106t. However, the present disclosure is not limited thereto. In other embodiments, the third circuit thickness 105t may be different from the fourth circuit thickness 106t.

In the present disclosure, when viewed from above (i.e., along the normal direction of substrate 100), the ratio of the projected area of the circuit pattern (i.e., the area of the circuit pattern itself overlapping the substrate) to the area of a selected region is called the circuit density or residual copper ratio. For example, when the projected area of the circuit pattern (i.e., the total area of the conductor viewed from above) is x, and the area of the selected region is y (where x≤y), the circuit density or residual copper ratio is defined as x/y (which may also be expressed as a percentage). The circuit density (or residual copper ratio) of this selected region will be used in subsequent processes to determine whether the region is filled with a buffer material. In some embodiments, the smallest area of a rectangle, circle, or other suitable shape that may cover the entire circuit pattern may be used as the selected region to determine the circuit density (or residual copper ratio) under this condition. However, the present disclosure is not limited thereto. In other embodiments, any suitable region may be arbitrarily selected as the selected region to determine the circuit density (or residual copper ratio) under this condition. In some embodiments, when there is no circuit pattern in the selected area, the circuit density (or residual copper ratio) of this area may be defined to be substantially 0%. Conversely, when the selected area is completely covered by a circuit pattern, the circuit density (or residual copper ratio) of this area may be defined to be substantially 100%.

As described above, the first circuit pattern 103 and the second circuit pattern 104 may have different circuit densities. For example, the first circuit pattern 103 may have a first circuit density (i.e., the ratio of the total top view area of the first circuit pattern 103 to the area 100A1), and the second circuit pattern 104 may have a second circuit density (i.e., the ratio of the total top view area of the second circuit pattern 104 to the area 100A2), wherein the second circuit density is less than the first circuit density. In other words, the first circuit pattern 103 is denser than the second circuit pattern 104 per unit area. For ease of understanding, FIG. 2 divides the substrate 100 into an upper right half (with the area 100A1) and an upper left half (with the area 100A2) of the same size by a dashed line DL, such that the area 100A1 is substantially the same as the area 100A2. However, as mentioned above, in other embodiments, the position of the dashed line DL may be arbitrarily chosen as needed, or the areas 100A1 and 100A2 may be arbitrarily defined to be different from each other.

Similarly, the third circuit pattern 105 and the fourth circuit pattern 106 may have different circuit densities. For example, the third circuit pattern 105 may have a third circuit density (i.e., the ratio of the total top view area of the third circuit pattern 105 to area 100B1), and the fourth circuit pattern 106 may have a fourth circuit density (i.e., the ratio of the total top view area of the fourth circuit pattern 106 to area 100B2), wherein the fourth circuit density is less than the third circuit density. In other words, the third circuit pattern 105 is denser than the fourth circuit pattern 106 per unit area. For ease of understanding, FIG. 2 divides the substrate 100 into a lower right half (with the area 100B1) and a lower left half (with the area 100B2) of the same size by a dashed line DL, such that area 100B1 is substantially the same as area 100B2. However, as mentioned above, in other embodiments, the position of the dashed line DL may be arbitrarily chosen as needed, or the areas 100B1 and 100B2 may be arbitrarily defined to be different from each other.

In some embodiments, the conductor layer 101 and/or the conductor layer 102 may be patterned by a combination of photolithography and etching processes. In some embodiments, the photolithography process may include photoresist application (e.g., spin-on coating, lamination), soft baking, mask alignment, exposure, post-exposure baking, photoresist developing, rinsing, drying (e.g., spin-drying and/or hard baking), other suitable photolithography techniques, and/or a combination thereof, but the present disclosure is not limited thereto. In some embodiments, the etching process may include dry etching, wet etching, other suitable etching, or a combination thereof, but the present disclosure is not limited thereto.

As shown in FIG. 3, following the steps described above, the buffer material 200 is disposed on the substrate 100. Specifically, the buffer material 200 is used to fill the gaps G inside the circuit pattern (e.g., the first circuit pattern 103), or to fill the copper-free area CF (i.e., the area without a circuit pattern) between two circuit patterns (e.g., between the first circuit pattern 103 and the second circuit pattern 104). In this way, the step difference between the surface of the substrate 100 (e.g., the upper surface 100A) and the upper surface of the circuit pattern (e.g., the upper surface 103U of the first circuit pattern 103) may be reduced, thereby enabling the formation of a dielectric layer with a flat surface in subsequent processes.

In some embodiments, the location of disposing the buffer material 200 may be determined based on the circuit density. For example, when the circuit density of a selected area is less than or equal to 50%, the buffer material 200 may be filled in this selected area. Conversely, when the circuit density of another selected area is greater than 50%, the buffer material 200 may not be filled in this selected area. Of course, the above values are merely examples, and the present disclosure is not limited thereto. A person having ordinary skills in the art may determine the threshold of circuit density corresponding to the disposing of the buffer material 200 according to design requirements. For example, “circuit density less than or equal to 80%” may be defined as the threshold, and the corresponding local area may be filled with the buffer material 200.

In other embodiments, the circuit pattern (e.g., the first circuit pattern 103) defines the gap G, and the buffer material 200 may fill at least 40% of the volume of the gap G. For example, the buffer material 200 may fill 40%, 50%, 60%, 70%, 80%, 90%, 100%, or any value or range between the above values of the gap G. When the buffer material 200 is filled too little (e.g., less than 40%), it may be difficult for the buffer material 200 to provide sufficient support in subsequent processes. Conversely, when the buffer material 200 is filled too much (e.g., more than 100%), the buffer material 200 may overflow the gap G and cover the upper surface of the circuit pattern, thereby affecting the dielectric constant between these components.

Similarly, the buffer material 200 may fill at least 40% of the volume of the copper-free area CF. For example, the buffer material 200 may fill 40%, 50%, 60%, 70%, 80%, 90%, 100% of the volume of the copper-free area CF, or any value or range between the above values.

As shown in FIG. 3, the buffer material 200 may be filled into all portions of the upper surface 100A of the substrate 100 that are not covered by the circuit pattern 101P. In other words, the entire upper surface 100A of the substrate 100 is completely covered by the circuit pattern 101P and the buffer material 200, and is not exposed to the outside. Of course, the present disclosure is not limited to this. In other embodiments (hereinafter), the buffer material 200 may be partially filled into all portions of the upper surface 100A of the substrate 100 that are not covered by the circuit pattern 101P. In this way, the entire upper surface 100A of the substrate 100 is partially covered by the circuit pattern 101P and the buffer material 200, while another portion is exposed to the outside.

Similar to the definition of circuit density above, in the present disclosure, when viewed from above (i.e., along the normal direction of the substrate 100), the ratio of the projected area of the circuit pattern 101P and the buffer material 200 (i.e., the total area of the circuit pattern 101P and the buffer material 200 overlapping with the substrate) to the area of a selected region is called the coverage density. In some embodiments, the buffer material 200 may be selectively filled on the upper surface 100A of the substrate 100 to make the coverage density of each local region on the substrate 100 consistent. In other words, when a region has a high circuit density, the buffer material 200 may be optionally not filled in this region, so that the coverage density of this region is substantially the circuit density. On the other hand, when another region has a lower circuit density, the buffer material may be optionally filled in this region until the coverage density of this region increases. In this way, the coverage density of each local region of the substrate 100 may be adjusted to be similar or even the same, thereby improving the planarization of the dielectric layer in subsequent processes.

In some embodiments, to improve the interface adhesion between the buffer material 200 and the substrate 100 and the circuit pattern 101P, the surfaces of the circuit pattern 101P (such as the upper surface 103U and the side surface 103S) and the exposed surfaces of the substrate 100 may be subjected to surface modification treatment before the buffer material 200 is applied. Surface modification treatment may include black oxide treatment, brown oxide treatment, micro-etching, plasma treatment, or coating with a coupling agent (e.g., a silane coupling agent).

Specifically, the aforementioned surface treatment may increase the surface roughness of the circuit pattern 101P, thereby enhancing its bonding strength with the buffer material 200 through mechanical interlocking. Simultaneously, if the buffer material 200 contains a resin component (such as epoxy resin), the coupling agent may form chemical bonds between the inorganic conductor interface and the organic polymer interface, thereby reducing the risk of delamination during thermal expansion.

Furthermore, after the buffer material 200 is disposed and cured, its upper surface may be roughened or activated again as needed to facilitate the formation of a tight bonding interface between the subsequently applied dielectric layer (not shown) and the buffer material 200 and the circuit pattern 101P. By controlling the matching of the coefficient of thermal expansion (CTE) between the buffer material 200 and the circuit pattern 101P (e.g., ensuring that the CTE difference between the two is less than or equal to 20 ppm/° C.), the reliability of the circuit board structure during thermal cycling tests may be further ensured.

As shown in FIG. 3, following the steps described above, the buffer material 210 may be filled into all portions of the lower surface 100B of the substrate 100 that are not covered by the circuit pattern 102P. In other words, the entire lower surface 100B of the substrate 100 is completely covered by both the circuit pattern 102P and the buffer material 210. Of course, the present disclosure is not limited to this. In other embodiments, the buffer material 210 may be partially filled into all portions of the lower surface 100B of the substrate 100 that are not covered by the circuit pattern 102P. In this way, the entire lower surface 100B of the substrate 100 is partially covered by both the circuit pattern 102P and the buffer material 210, while another portion is exposed to the outside.

In some embodiments, before applying the buffer material 210, the surface of the circuit pattern 102P and the exposed surface of the substrate 100 may be subjected to surface modification treatment. Reference may be made to the above descriptions, and details are omitted herein for brevity.

In some embodiments, the buffer material 200 and/or the buffer material 210 may include epoxy fiberglass board (FR-4), Ajinomoto Build-Up Film (ABF), bismaleimide triazine (BT) resin, other suitable materials, or a combination thereof, but the present disclosure is not limited thereto. In some embodiments, the buffer material 200 and/or the buffer material 210 may include a mixture, such as a combination of epoxy resin and filler. For example, the epoxy resin may include bisphenol F/epichlorohydrin copolymer, and the filler may include silicon dioxide. The above mixture may be a solvent-free thermosetting material and may have the effects of easy venting (avoiding voids) and high insulation. In some embodiments, the buffer material 200 and/or the buffer material 210 may also include functional particles dispersed therein, such as refractory particles, low dielectric constant particles, or other suitable particles. In some embodiments, the buffer material 200 and/or the buffer material 210 may include a thermosetting material or a photocurable material to prevent unintended secondary softening or melting in subsequent processes.

In some embodiments, the step of disposing the buffer material 200 and/or the buffer material 210 may employ one or a combination of screen printing, temporary lamination (also referred to as tack lamination). For example, a suitable application method may be selected based on conditions such as the type of buffer material 200 and/or the amount applied.

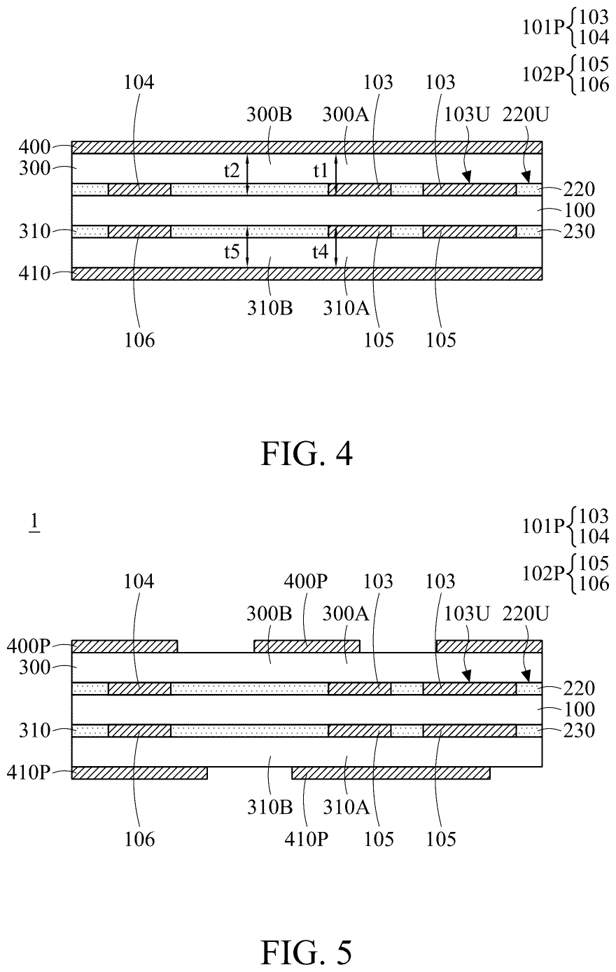

As shown in FIG. 4, following the above steps, the buffer material 200 is cured to form the buffer structure 220, wherein the buffer structure 220 is electrically insulated from the circuit pattern 101P. On the other hand, the buffer material 210 is cured to form the buffer structure 230, wherein the buffer structure 230 is electrically insulated from the circuit pattern 102P. In some embodiments, the buffer material 200 and the buffer material 210 may be transformed from a fluid state into the solid buffer structure 220 and the buffer structure 230 by thermosetting, photocuring, or a combination thereof.

In some embodiments, to ensure the flatness of the structure, a planarization process may be further performed after the buffer material has been cured. For example, the planarization process may include grinding, polishing, chemical mechanical planarization (CMP), or buffing. Specifically, the planarization process may remove excess buffer material overflowing onto the upper surface of the circuit pattern 101P (or the circuit pattern 102P), such that the upper surface 220U of the buffer structure 220 is substantially coplanar with the upper surface (e.g., the upper surface 103U) of the circuit pattern (e.g., the first circuit pattern 103).

It should be noted that by filling the gap G and the copper-free area CF with the buffer structure 220, the volume difference caused by the uneven distribution of the circuit pattern may be compensated. During subsequent lamination of the dielectric layer, collapse or thickness deviation caused by uneven flow of the dielectric material may be avoided. Furthermore, in some embodiments, the composition of the buffer material 200 may be adjusted to control its curing shrinkage rate. For example, by adding the aforementioned functional particles (such as silicon dioxide) to the buffer material 200, its curing shrinkage rate may be reduced and made closer to the expansion characteristics of the circuit pattern 101P, thereby improving the dimensional stability of the structure after curing.

Following the above steps, a lamination process is performed at a lamination temperature to form the dielectric layer 300 on the circuit pattern 101P (including the first circuit pattern 103 and the second circuit pattern 104) and the buffer structure 220. In some embodiments, the dielectric material may be softened or melted by applying heat or pressure to form a dielectric material layer with a blanket structure on the substrate 100, and then the dielectric material layer is cured to form the dielectric layer 300. In some cases, to avoid the buffer structure 220 from softening or melting again, the glass transition temperature or the melting point of the buffer structure 220 needs to be higher than the lamination temperature. In other words, the material of the buffer structure 220 may be different from the material of the dielectric layer 300. Alternatively, both the buffer structure 220 and the dielectric layer 300 may include the same thermosetting or photocurable material, and the above-mentioned problem may be avoided by the characteristic that it does not soften after curing. In this case, the material of the buffer structure 220 may be the same as the material of the dielectric layer 300.

In some embodiments, the dielectric layer 300 may be divided into multiple portions according to its location. For example, the dielectric layer 300 may include the first portion 300A and the second portion 300B. The first portion 300A covers the circuit pattern 101P (e.g., the first circuit pattern 103 or the second circuit pattern 104), and the first portion 300A and the circuit pattern 101P together have the first thickness t1. The second portion 300B covers the buffer structure 220, and the second portion 300B and the buffer structure 220 together have the second thickness t2. In some embodiments, |(t1−t2)|≤30 μm. For example, the difference between the first thickness t1 and the second thickness t2 may be 30 μm, 25 μm, 20 μm, 15 μm, 10 μm, 5 μm, 0 μm, or any value or range between the above values. In some embodiments, |(t1−t2)|/(t1+t2) may be defined as the degree of thickness variation between the first portion 300A and the second portion 300B, and |(t1−t2)|/(t1+t2)≤20 %. For example, the degree of thickness variation may be 20%, 15%, 10%, 5%, 0%, or any value or range between the above values. As expressed by the formula, the smaller the difference between the first thickness t1 and the second thickness t2, the higher the flatness of the wiring area and the non-wiring area.

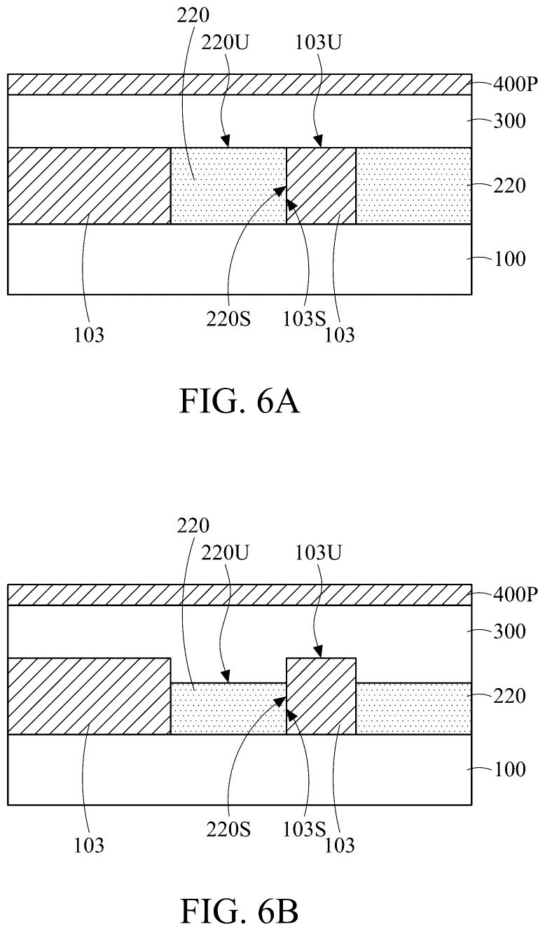

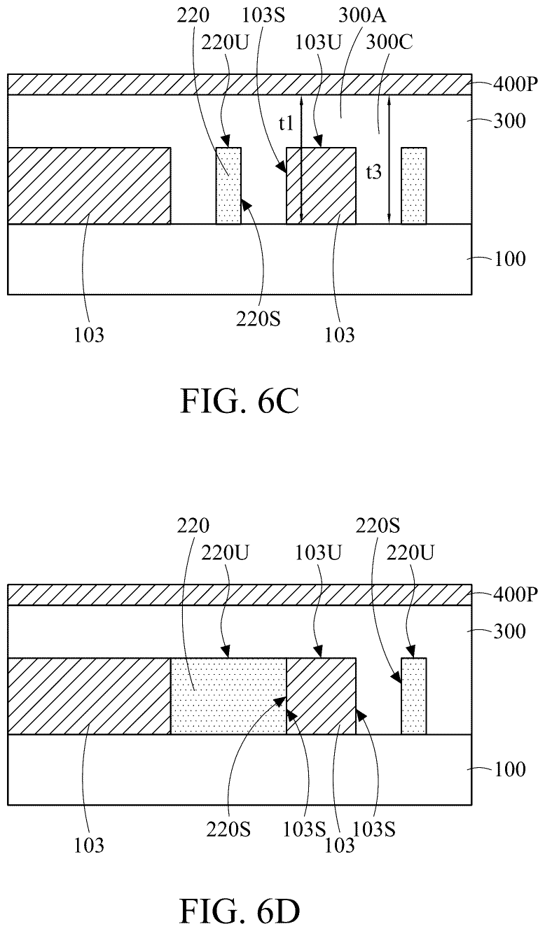

As shown in FIG. 6C, in some embodiments, although the buffer structure 220 only covers a portion of the exposed upper surface 100A of the substrate 100, a similar or identical support effect may still be achieved. In this case, the dielectric layer 300 further includes the third portion 300C. The third portion 300C is in contact with the substrate 100, wherein the third portion 300C has the third thickness t3. Specifically, there is no circuit pattern 101P (e.g., the first circuit pattern 103) and buffer structure 220 between the third portion 300C and the substrate 100, that is, the third thickness t3 is the thickness of the dielectric layer 300 itself. In some embodiments, |(t1−t3)|≤30 μm. For example, the difference between the first thickness t1 and the third thickness t3 may be 30 μm, 25 μm, 20 μm, 15 μm, 10 μm, 5 μm, 0 μm, or any value or range between the above values. In some embodiments, |(t1−t3)|/(t1+t3) may be defined as the degree of thickness variation between the first portion 300A and the third portion 300C, and |(t1−t3)|/(t1+t3)≤20 %. For example, the degree of thickness variation may be 20%, 15%, 10%, 5%, 0%, or any value or range between the above values. As expressed by the formula, the smaller the difference between the first thickness t1 and the third thickness t3, the higher the degree of flatness achieved by providing the buffer structure 220.

As shown in FIG. 4, following the steps described above, another lamination process is performed at the lamination temperature to form the dielectric layer 310 on the circuit pattern 102P (including the third circuit pattern 105 and the fourth circuit pattern 106) and the buffer structure 230. In some embodiments, the dielectric material may be softened or melted by applying heat or pressure to form a dielectric material layer with a blanket structure on the substrate 100, and the dielectric material layer is cured to form the dielectric layer 310. In some cases, to prevent the buffer structure 230 from softening or melting again, the glass transition temperature or melting point of the buffer structure 230 needs to be higher than the lamination temperature. Alternatively, both the buffer structure 230 and the dielectric layer 310 may include the same thermosetting or photocurable material to avoid the above-mentioned problems by virtue of not softening after curing. In this case, the material of the buffer structure 230 may be the same as the material of the dielectric layer 310.

In some embodiments, the dielectric layer 310 may be divided into multiple portions according to its location. For example, the dielectric layer 310 may include the fourth portion 310A and the fifth portion 310B. The fourth portion 310A covers the circuit pattern 102P, and the fourth portion 310A and the circuit pattern 102P together have a fourth thickness t4. The fifth portion 310B covers the buffer structure 230, and the fifth portion 310B and the buffer structure 230 together have the fifth thickness t5. In some embodiments, |(t4−t5)|≤30 μm. For example, the difference between the fourth thickness t4 and the fifth thickness t5 may be 30 μm, 25 μm, 20 μm, 15 μm, 10 μm, 5 μm, 0 μm, or any value or range between the above values. In some embodiments, |(t4−t5)|/(t4+t5) may be defined as the degree of thickness variation between the fourth part 310A and the fifth part 310B, and |(t4−t5)|/(t4+t5)≤20%. For example, the degree of thickness variation may be 20%, 15%, 10%, 5%, 0%, or any value or range between the above values.

A circuit board structure with a flat upper surface (the outermost surface) may be obtained using the process described above. In some embodiments, lamination processes may be performed on the circuit board structure to form a more complex and multi-layered circuit board structure. For example, following the above steps, the conductor layer 400 may be formed on the dielectric layer 300, and the conductor layer 410 may be formed on the dielectric layer 310. In some embodiments, the conductor layer 400 and/or the conductor layer 410 may include aluminum (Al), copper (Cu), an alloy thereof, or a compound thereof, but the present disclosure is not limited thereto. As shown in FIG. 5, following the above steps, the conductor layer 400 and/or the conductor layer 410 may be patterned to form the circuit pattern 400P and the circuit pattern 410P. For example, the conductor layer 400 and/or the conductor layer 410 may be patterned using a combination of photolithography and etching processes to obtain the circuit board structure 1.

FIGS. 6A to 6D are enlarged cross-sectional schematic diagrams illustrating the buffer structure and the circuit pattern according to some embodiments of the present disclosure. In these embodiments, the first circuit pattern 103 in the circuit pattern 101P is used as an example for illustration, but these configurations may be applied to other circuit patterns (e.g., the second circuit pattern 104 in the circuit pattern 101P, or the third circuit pattern 105 and the fourth circuit pattern 106 in the circuit pattern 102P) as needed.

As shown in FIG. 6A, in some embodiments, the buffer structure 220 completely fills the gaps between the lines in the first circuit pattern 103 and is coplanar with (or at the same height as) the first circuit pattern 103. In this case, the upper surface 220U of the buffer structure 220 is coplanar with the upper surface 103U of the circuit pattern 101P (i.e., the first circuit pattern 103), and the side surface 220S of the buffer structure 220 is in contact with the side surface 103S of the circuit pattern 101P (i.e., the first circuit pattern 103).

As shown in FIG. 6B, in some embodiments, the buffer structure 220 partially fills the gaps between the lines in the first circuit pattern 103 and is not coplanar with the first circuit pattern 103. In this case, the upper surface 220U of the buffer structure 220 is lower than the upper surface 103U of the circuit pattern 101P (i.e., the first circuit pattern 103), while the side surface 220S of the buffer structure 220 is in contact with the side surface 103S of the circuit pattern 101P (i.e., the first circuit pattern 103).

As shown in FIG. 6C, in some embodiments, the buffer structure 220 partially fills the gaps between lines in the first circuit pattern 103 and is coplanar with the first circuit pattern 103. In this case, the upper surface 220U of the buffer structure 220 is coplanar with the upper surface 103U of the circuit pattern 101P (i.e., the first circuit pattern 103), while the side surface 220S of the buffer structure 220 is not in contact with the side surface 103S of the circuit pattern 101P (i.e., the first circuit pattern 103). In this case, the top view shape of the buffer structure 220 may include a triangle, a circle, an ellipse, a rectangle, a polygon, or any other suitable shape. Alternatively, the side view shape of the buffer structure 220 may include a rectangle, a pyramid, a trapezoid, a funnel shape, a dumbbell shape, or other suitable shapes.

As shown in FIG. 6D, in some embodiments, the buffer structure 220 partially fills the gaps between lines in the first circuit pattern 103 and may optionally be coplanar with or not coplanar with the first circuit pattern 103. In this case, the upper surface 220U of the buffer structure 220 may be coplanar with or lower than the upper surface 103U of the circuit pattern 101P (i.e., the first circuit pattern 103), while the side surface 220S of the buffer structure 220 may or may not be in contact with the side surface 103S of the circuit pattern 101P (i.e., the first circuit pattern 103). In other words, a person having ordinary skills in the art may adjust the arrangement of the buffer structure according to their needs, such as how much substrate 100 it covers, how much gap (or copper-free area) it fills, and whether it is in contact with the circuit pattern, thereby improving design flexibility while achieving similar or identical support effects.

In summary, the present disclosure discloses a buffer structure disposed in the gaps between adjacent lines in a circuit pattern, or in the copper-free area (i.e., the area without a circuit pattern) between two circuit patterns, to mitigate problems caused by uneven circuit density. Specifically, the buffer structure may partially or completely fill these areas and act as a support to allow the dielectric layer in subsequent processes to be laid flat. In other words, the present disclosure provides a circuit board structure with excellent dielectric thickness uniformity and a manufacturing method of the same.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a substrate;
a circuit pattern disposed on the substrate;
a buffer structure disposed on the substrate and electrically insulated from the circuit pattern; and
a dielectric layer, comprising:
a first portion covering and in contact with an upper surface of the circuit pattern; and
a second portion covering and in contact with an upper surface of the buffer structure.

2. The circuit board structure as claimed in claim 1, wherein the first portion and the circuit pattern together have a first thickness t1, and the second portion and the buffer structure together have a second thickness t2, wherein |(t1−t2)|≤30 μm.

3. The circuit board structure as claimed in claim 1, wherein the first portion and the circuit pattern together have a first thickness t1, and the second portion and the buffer structure together have a second thickness t2, wherein |(t1−t2)|/(t1+t2)≤20%.

4. The circuit board structure as claimed in claim 1, wherein the dielectric layer further comprises:
a third portion covering and in contact with an upper surface of the substrate.

5. The circuit board structure as claimed in claim 4, wherein the first portion and the circuit pattern together have a first thickness t1, and the third portion has a third thickness t3, and |(t1−t3)|≤30 μm.

6. The circuit board structure as claimed in claim 4, wherein the first portion and the circuit pattern together have a first thickness t1, and the third portion has a third thickness t3, and |(t1−t3)|/(t1+t3)≤20%.

7. The circuit board structure as claimed in claim 1, wherein the upper surface of the buffer structure is coplanar with the upper surface of the circuit pattern.

8. The circuit board structure as claimed in claim 7, wherein a side surface of the buffer structure is not in contact with a side surface of the circuit pattern.

9. The circuit board structure as claimed in claim 1, wherein the upper surface of the buffer structure is lower than the upper surface of the circuit pattern.

10. The circuit board structure as claimed in claim 9, wherein a side surface of the buffer structure is in contact with a side surface of the circuit pattern.

11. The circuit board structure as claimed in claim 1, wherein the circuit pattern defines a gap and the buffer structure fills at least 40% of the volume of the gap.

12. The circuit board structure as claimed in claim 1, wherein a material of the buffer structure is different from a material of the dielectric layer.

13. A manufacturing method of a circuit board structure, comprising:
forming a circuit pattern on a substrate;
disposing a buffer material on the substrate;
curing the buffer material to form a buffer structure, wherein the buffer structure is electrically insulated from the circuit pattern; and
performing a lamination process at a lamination temperature to form a dielectric layer on the circuit pattern and the buffer structure,
wherein a glass transition temperature or a melting point of the buffer structure is higher than the lamination temperature.

14. The manufacturing method of the circuit board structure as claimed in claim 13, wherein the dielectric layer comprises:
a first portion covering and in contact with an upper surface of the circuit pattern; and
a second portion covering and in contact with an upper surface of the buffer structure.

15. The manufacturing method of the circuit board structure as claimed in claim 14, wherein the first portion and the circuit pattern together have a first thickness t1, the second portion and the buffer structure together have a second thickness t2, and |(t1−t2)|≤30 μm.

16. The manufacturing method of the circuit board structure as claimed in claim 14, wherein the first portion and the circuit pattern together have a first thickness t1, the second portion and the buffer structure together have a second thickness t2, and |(t1−t2)|/(t1+t2)≤20%.

17. The manufacturing method of the circuit board structure as claimed in claim 14, wherein the first portion and the circuit pattern together have a first thickness t1, and the dielectric layer further comprises:
a third portion covering and in contact with an upper surface of the substrate,
wherein the third portion has a third thickness t3, and |(t1−t3)|≤30 μm.

18. The manufacturing method of the circuit board structure as claimed in claim 14, wherein the first portion and the circuit pattern together have a first thickness t1, and the dielectric layer further comprises:
a third portion covering and in contact with an upper surface of the substrate, wherein the third portion has a third thickness t3, and |(t1−t3)|/(t1+t3)≤20%.

19. The manufacturing method of the circuit board structure as claimed in claim 13, wherein the circuit pattern defines a gap and the buffer structure fills at least 40% of the volume of the gap.

20. The manufacturing method of the circuit board structure as claimed in claim 13, wherein the step of disposing the buffer material on the substrate comprises:
disposing the buffer material on the substrate using a screen printing process.
